(19) United States
(12) Patent Application Publication
(10) Pub. No.: US 2010/0147581 A1
(43) Pub. Date: Jun. 17, 2010

(54) FLEXIBLE SUBSTRATE AND OPENING/CLOSING ELECTRONIC DEVICE

(75) Inventor: Masatosi Mitomi, Tokyo (JP)

Correspondence Address: DITTHAVONG MORI & STEINER, P.C., 918 Prince Street, Alexandria, VA, 22314, US

(73) Assignee: SUMITOMO BAKELITE CO., LTD, Tokyo (JP)

(21) Appl. No.: 12/600,457

(22) PCT Filed: May 23, 2008
(86) PCT No.: PCT/JP2008/001296

§ 371 Date: Nov. 16, 2009

(30) Foreign Application Priority Data
May 29, 2007 (JP) 2007-141358

(51) Int. Cl. H05K 1/00; H05K 7/00

(52) U.S. Cl. 174/520; 174/254

(57) ABSTRACT

A flexible substrate (200) includes a recessed portion formed on a right edge portion of a first linear portion (210) continuously extending backward from a left end portion of an intermediate linear portion (230). In the case of inserting the flexible substrate (200) for example through a hollow hinge portion (101) openably and closably connecting a first and a second device body (110), (120) of an opening/closing type electronic device (100), upon inserting the first linear portion (210) through the first opening (112) of the first cylindrical hinge portion (118), constituting a part of the hollow hinge portion (101), the recessed portion of the first linear portion (210) is located so as to oppose a right end inner surface of the first opening (112), with a gap therebetween. Accordingly, although the intermediate linear portion (230) is twisted by the opening or closing action of the opening/closing type electronic device (100), disconnection due to interference of the first linear portion (210) with the right end inner surface of the first opening (112) can be prevented. Therefore, the flexible substrate can prevent the trouble of the opening/closing type electronic device, without the need to largely modify the design of an essential component.

### TECHNICAL FIELD

The present invention relates to a flat flexible substrate including a first linear portion, an intermediate linear portion, and a second linear portion continuously formed in a crank shape, and to an opening/closing type electronic device that includes the flexible substrate.

### BACKGROUND ART

Some opening/closing type electronic devices are currently available, such as a mobile phone terminal, which include a first device body and a second device body that can be opened and closed with respect to each other, for better portability. In such opening/closing type electronic devices, the first device body and the second device body are openably and closably connected, for example, via a hollow hinge portion.

For example, a mobile phone terminal 300 representing such opening/closing type electronic devices includes, as shown in FIG. 6, a first device body 110 including therein a first rigid substrate 133 and a second device body 120 including therein a second rigid substrate 134, which are connected via a hollow hinge portion 101 so as to be freely opened and closed.

To connectors 411, 421 of a crank-shaped flexible substrate 400 inserted through the hollow hinge portion 101, the first rigid substrate 133 and the second rigid substrate 134 are respectively connected.

The first device body 110 includes a first body housing 111 including therein a first rigid substrate 133, and a first cylindrical hinge portion 118 integrally formed at an end portion of the first body housing 111 so as to constitute a part of the hollow hinge portion 101, and at the position where the first body housing 111 and the first hinge portion 118 connect, a first opening 112 is provided, through which the flexible substrate 400 is inserted.

The second device body 120 includes a second body housing 121 including therein a second rigid substrate 134, and a second cylindrical hinge portion 128 integrally formed at an end portion of the second body housing 121 so as to constitute a part of the hollow hinge portion 101, and at the position where the second body housing 121 and the second hinge portion 128 connect, a second opening 122 is provided, through which the flexible substrate 400 is inserted.

The flexible substrate 400 includes a first linear portion 410 continuously extending from the first rigid substrate 133 and inserted through the first opening 112, a second linear portion 420 continuously extending from the second rigid substrate 134 and inserted through the second opening 122, and an intermediate linear portion 430 being continuous with the first linear portion 410 and the second linear portion 420 orthogonally thereto, and enclosed inside the hollow hinge portion 101.

In the mobile phone terminal 300 thus configured, since the first device body 110 and the second device body 120 connected via the hollow hinge portion 101 can be freely opened and closed, both portability and operability can be attained.

In addition, the first rigid substrate 133 provided in the first device body 110 and the second rigid substrate 134 provided in the second device body 120 can communicate with each other through the flexible substrate 400.

Regarding the opening/closing type electronic device configured as above, various proposals have been made (for example, patented documents 1 to 3 cited below).

Patented document 1: JP-A No. 2005-303888

Patented document 2: JP-A No. 2005-147205

Patented document 3: JP-A No. 2004-273555

### DISCLOSURE OF THE INVENTION

In the foregoing mobile phone terminal 300, a connector 135 of the first rigid substrate 133 may be located at a position slightly displaced to the right from a rear portion of the first opening 112. In this case, the first linear portion 410 of the flexible substrate 400 linearly extends forward from the position of the connector 135.

Likewise, a connector 136 of the second rigid substrate 134 may be located at a position slightly displaced to the left from a frontal portion of the second opening 122, so that the second linear portion 420 of the flexible substrate 400 linearly extends backward from the position of the connector 136.

In the mobile phone terminal 300 thus configured, however, when the first device body 110 and the second device body 120 are opened or closed the intermediate linear portion 430 of the flexible substrate 400 is twisted, and thereby contracts in a left and right direction, which corresponds to a longitudinal direction thereof.

Then the first linear portion 410 being continuous with the left end portion of the intermediate linear portion 430 is displaced to the right, and the second linear portion 420 being continuous with the right end portion is displaced to the left. In this case, the first linear portion 410 interferes with a right end portion of the first opening 112, and the second linear portion 420 with a left end portion of the second opening 122, and such interference may provoke a trouble such as wire disconnection in the flexible substrate 400.

For example, modifying the design of the shape of the first and the second opening 112, 122 or the position of the connectors 135, 136 may lead to solution of the foregoing trouble. However, since mass production is a key issue with the mobile phone terminal 300, various components are employed in common among a plurality of models. Accordingly, it is not easy to modify the design of essential components such as the first and the second device body 110, 120, and the first and the second rigid substrate 133, 134.

The present invention has been accomplished in view of the foregoing problem, and provides a flexible substrate that can eliminate the drawback of the opening/closing type electronic device without the need to largely modify the design of an essential component, and an opening/closing type electronic device that includes such flexible substrate.

According to the present invention, there is provided a flexible substrate, of a flat shape and including a first linear portion, an intermediate linear portion, and a second linear portion continuously formed in a crank shape, wherein a left end portion of the intermediate linear portion having a shape prolonged in a left and right direction is continuous with a front end portion of the first linear portion having a shape prolonged in a back and forth direction; a rear end portion of the second linear portion having a shape prolonged in a back and forth direction is continuous with a right end portion of the intermediate linear portion; and the first linear portion includes a recessed portion at least on a right edge portion thereof.

In the flexible substrate according to the present invention, since the first linear portion continuously extending backward from the left end portion of the intermediate linear portion includes the recessed portion on the right edge portion thereof, the recessed portion allows circumventing a projecting portion of the electronic device.

Accordingly, in the case where the flexible substrate is inserted, for example, through the hollow hinge portion openably and closably connecting the first device body and the second device body of the opening/closing type electronic device, upon inserting the first linear portion through the first opening of the first cylindrical hinge portion of the first device body, constituting a part of the hollow hinge portion, the recessed portion of the first linear portion is located so as to oppose a right end inner surface of the first opening, with a gap therebetween.

According to the present invention, there is provided an opening/closing type electronic device including a first device body and a second device body openably and closably connected via a hollow hinge portion through which a flexible substrate is inserted, wherein the first device body includes a first cylindrical hinge portion including a first opening and constituting a part of the hollow hinge portion; the first linear portion of the flexible substrate according to the present invention is inserted through the first opening; and the recessed portion of the first linear portion is located so as to oppose a right end inner surface of the first opening, with a gap therebetween.

The opening/closing type electronic device according to the present invention can, therefore, attain both portability and operability, since the first device body and the second device body connected via the hollow hinge portion can be freely opened and closed. In addition, rigid substrates and so forth provided inside the first device body and the second device body can make communication through the flexible substrate.

Although the flexible substrate is inserted through the first opening located at the position where the first body housing of the first device body and the first hinge portion connect, the first linear portion of the flexible substrate is located so as to circumvent the right end inner surface of the first opening. Accordingly, even though the intermediate linear portion of the flexible substrate is twisted by the opening or closing action of the first device body and the second device body, the first linear portion is prevented from interfering with the right end inner surface of the first opening.

It is to be noted that the constituents of the present invention do not necessarily have to be individually independent, but a plurality of constituents may form a piece of component; a constituent may be composed of a plurality of components; a constituent may be a part of another constituent; and a part of a constituent may also serve as a part of another constituent.

Although the present invention specifies the back and forth, and left and right direction, those are merely for convenience sake for simplifying the explanation of positional relations between the constituents of the present invention, and in no way intended to limit the direction in the manufacturing process or in the use of the product, in the execution of the present invention.

Further, the shape defined based on the back and forth, or left and right direction according to the present invention does not limit the direction in which the product manufactured according to the present invention is to be viewed. Therefore, the plan-view shape of the flexible substrate according to the present invention is reversed left and right depending on whether viewed from above or from below. Therefore, the flexible substrate according to the present invention intrinsically bears a mirror-symmetrical plan-view shape reversed left and right.

In the flexible substrate according to the present invention, since the first linear portion continuously extending backward from the right end portion of the intermediate linear portion includes the recessed portion on the right edge portion, the recessed portion allows circumventing a projecting portion of the electronic device. In the case where the flexible substrate is inserted, for example, through the hollow hinge portion openably and closably connecting the first device body and the second device body of the opening/closing type electronic device, upon inserting the first linear portion through the first opening of the first cylindrical hinge portion of the first device body, constituting a part of the hollow hinge portion, the recessed portion of the first linear portion is located so as to oppose a right end inner surface of the first opening, with a gap therebetween. Accordingly, although the intermediate linear portion is twisted by the opening or closing action of the opening/closing type electronic device, the first linear portion is prevented from interfering with the right end inner surface of the first opening, and therefore a trouble such as wire disconnection because of the interference can be prevented.

In the opening/closing type electronic device according to the present invention, although the flexible substrate is inserted through the first opening of the first hinge portion of the first device body, the first linear portion of the flexible substrate is located so as to go around the right end inner surface of the first opening, because of the recessed portion on the right edge portion. Accordingly, even though the intermediate linear portion of the flexible substrate is twisted by the opening or closing action of the first device body and the second device body, the first linear portion is prevented from interfering with the right end inner surface of the first opening, and therefore a trouble such as wire disconnection because of the interference can be prevented.

### BRIEF DESCRIPTION OF THE DRAWINGS

The above and other objects, features and advantages will become more apparent through a preferred embodiment described hereunder and the following accompanying drawings.

FIG. 1 is a cross-sectional plan view showing an internal structure of a mobile phone terminal, which is an embodiment of an opening/closing type electronic device according to the present invention;

FIG. 2 is an exploded perspective view showing an assembly structure of the mobile phone terminal;

FIG. 3 is an enlarged cross-sectional plan view showing the internal structure of the mobile phone terminal;

FIG. 4 is a cross-sectional plan view showing an internal structure of a mobile phone terminal, exemplifying a variation of the opening/closing type electronic device;

FIG. 5 is a cross-sectional plan view showing an internal structure of a mobile phone terminal, exemplifying another variation of the opening/closing type electronic device; and

FIG. 6 is a fragmentary transverse cross-sectional view showing an internal structure of a mobile phone terminal, exemplifying a conventional opening/closing type electronic device.

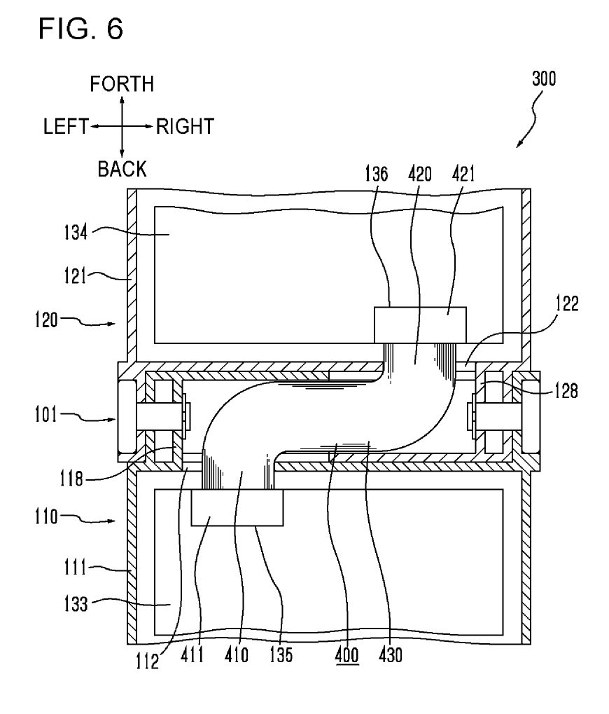

### BEST MODE FOR CARRYING OUT THE INVENTION

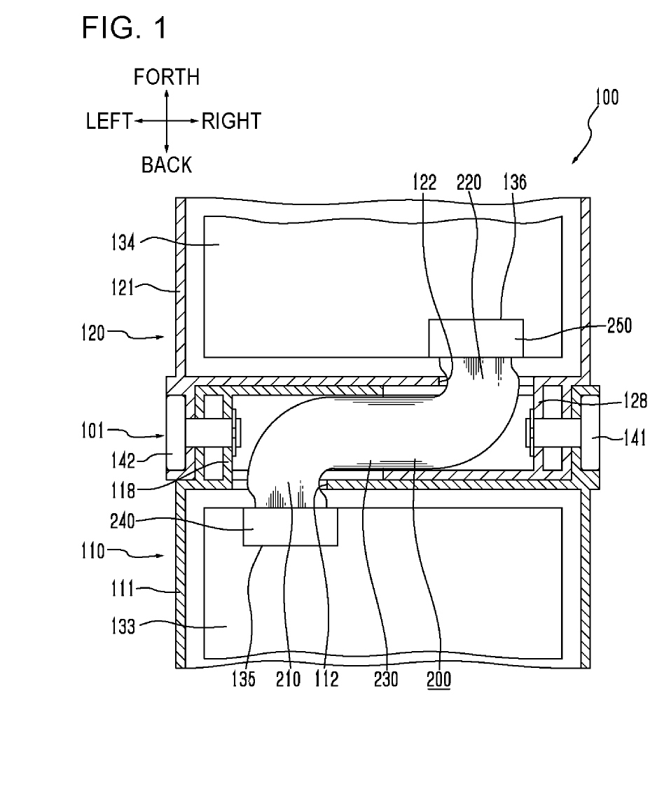

An embodiment of the present invention will be described hereunder, referring to FIGS. 1 to 3. To describe the embodiment, back and forth, left and right, and upper and lower directions will be referred to as shown in the drawings. It should be noted, however, that those directions are merely for convenience sake for simplifying the description, and in no way intended to limit the direction in the manufacturing process or in the use of the product, in the execution of the present invention.

A flexible substrate 200 according to this embodiment is flatly formed and includes a first linear portion 210, an intermediate linear portion 230, and a second linear portion 220 continuously formed in a crank shape. In the flexible substrate 200, a left end portion of the intermediate linear portion 230 having a shape prolonged in a left and right direction is continuous with a front end portion of the first linear portion 210 having a shape prolonged in a back and forth direction.

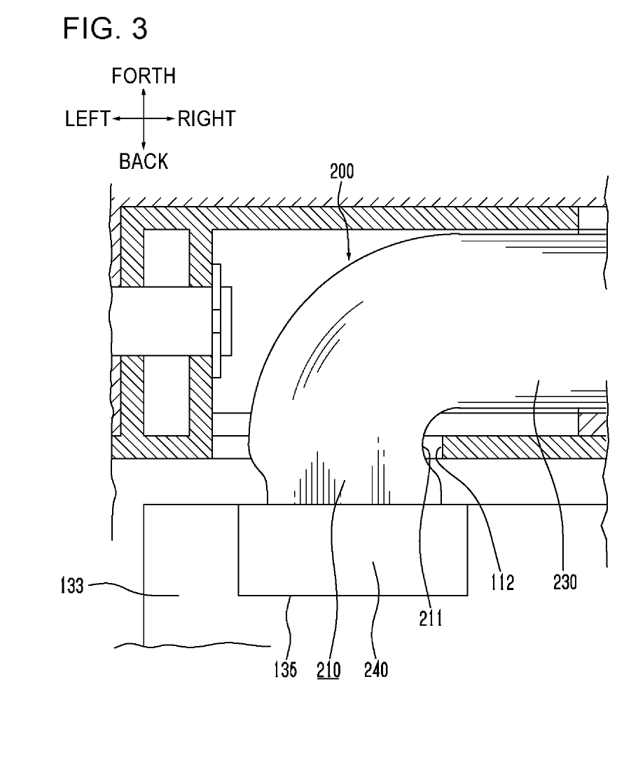

Also, a rear end portion of the second linear portion 220 having a shape prolonged in a back and forth direction is continuous with a right end portion of the intermediate linear portion 230. Here, the first linear portion 210 includes a recessed portion 211 at least on a right edge portion thereof, as shown in FIG. 3.

To be more detailed, the first linear portion 210 is of such a recessed shape that an intermediate portion thereof forms an arcuate curve toward the left, at least from the front end portion and the rear end portion thereof. Also, a rear edge portion of the intermediate linear portion 230 is continuous with an inner edge portion of the arcuate recessed portion 211 of the first linear portion 210.

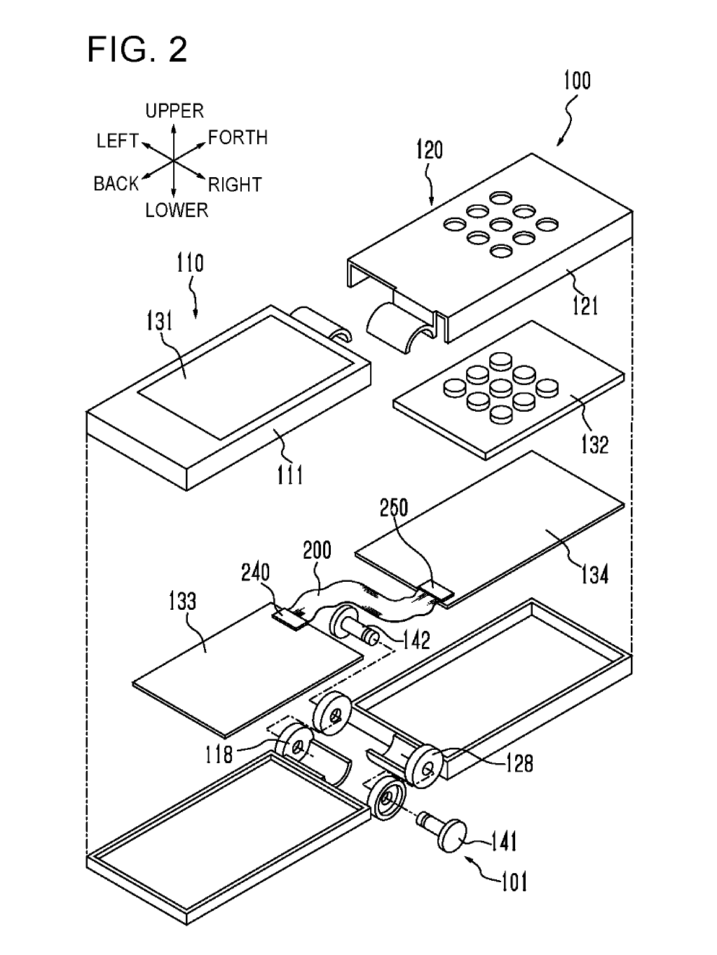

The mobile phone terminal 100, exemplifying the opening/closing type electronic device according to this embodiment includes, as shown in FIGS. 1 and 2, a first device body 110 including therein a first rigid substrate 133, and a second device body 120 including therein a second rigid substrate 134, which are openably and closably connected via a hollow hinge portion 101, and the first rigid substrate 133 and the second rigid substrate 134 are connected through the crank-shaped flexible substrate 200 inserted through the hollow hinge portion 101.

The first device body 110 includes a first body housing 111 including therein the first rigid substrate 133, and a first cylindrical hinge portion 118 integrally formed at an end portion of the first body housing 111 so as to constitute a part of the hollow hinge portion 101, and at the position where the first body housing 111 and the first hinge portion 118 connect, a first opening 112 is provided, through which the flexible substrate 200 is inserted.

The second device body 120 includes a second body housing 121 including therein the second rigid substrate 134, and a second cylindrical hinge portion 128 integrally formed at an end portion of the second body housing 121 so as to constitute a part of the hollow hinge portion 101, and at the position where the second body housing 121 and the second hinge portion 128 connect, a second opening 122 is provided, through which the flexible substrate 200 is inserted.

The flexible substrate 200 includes the first linear portion 210 continuously extending from the first rigid substrate 133 and inserted through the first opening 112, the second linear portion 220 continuously extending from the second rigid substrate 134 and inserted through the second opening 122, and the intermediate linear portion 230 being continuous with the first linear portion 210 and the second linear portion 220 orthogonally thereto and enclosed inside the hollow hinge portion 101.

The first linear portion 210 is of such a shape that circumvents an end portion of the first opening 112 on the side where the first linear portion 210 and the intermediate linear portion 230 connect, and the second linear portion 220 is of such a shape that circumvents an end portion of the second opening 122 on the side where the second linear portion 220 and the intermediate linear portion 230 connect.

To be more detailed, the first device body 110 and the second device body 120 are respectively of a box shape flat in an up and down direction and slender in a back and forth direction, and divided into an upper part and a lower part. Inside the first and the second body housing 111, 121, the first and the second rigid substrate 133, 134 of a rectangular shape in a plan view are respectively installed.

Also, on the upper face of the first device body 110, a display unit 131 such as a liquid crystal display (LCD) is located. On the upper face of the second device body 120, a keyboard unit 132 is provided. The display unit 131 and the keyboard unit 132 are implemented on the surface of the first rigid substrate 133 and the second rigid substrate 134, respectively.

The first hinge portion 118 of the first device body 110 and the second hinge portion 128 of the second device body 120 are also respectively divided into an upper and a lower part. The first and the second hinge portion 118, 128 has a left end portion and a right end portion respectively formed in a disk shape, and are rotatably connected with an axle bolt 141, 142 inserted through the disk-shaped portion.

The first opening 112 is formed to a predetermined position to the right from an inner left end portion of the first hinge portion 118. On the first rigid substrate 133, a connector 135 is mounted at a position slightly displaced to the right from a rear portion of the first opening 112.

To the connector 135 of the first rigid substrate 133, a connector 240, provided on the rear end portion of the first linear portion 210 of the flexible substrate 200, is connected. The first linear portion 210 is not linearly formed ahead of the connector 240, but formed in such a curved shape that circumvents the right end portion of the first opening 112 to the left.

The second opening 122 is formed to a predetermined position to the left from an inner right end portion of the second hinge portion 128. On the second rigid substrate 134, a connector 136 is mounted at a position slightly displaced to the left from a frontal portion of the second opening 122.

To the connector 136 of the second rigid substrate 134, a connector 250, provided on the front end portion of the second linear portion 220 of the flexible substrate 200, is connected. The second linear portion 220 is not linearly formed behind the connector 250, but formed in such a curved shape that circumvents the left end portion of the second opening 122 to the right.

The foregoing structure of the mobile phone terminal 100 according to this embodiment allows the first device body 110 and the second device body 120 connected via the hollow hinge portion 101 to be freely opened and closed, thereby attaining both portability and operability.

In addition, the first rigid substrate 133 provided in the first device body 110 and the second rigid substrate 134 provided in the second device body 120 can communicate with each other through the flexible substrate 200.

In the mobile phone terminal 100 according to this embodiment, the connector 135 of the first rigid substrate 133 is located at a position slightly displaced to the right from the rear portion of the first opening 112, and the connector 240 on the rear end portion of the first linear portion 210 of the flexible substrate 200 is connected to the connector 135.

Likewise, the connector 136 of the second rigid substrate 134 is located at a position slightly displaced to the left from the frontal portion of the second opening 122, and the connector 250 on the front end portion of the second linear portion 220 of the flexible substrate 200 is connected to the connector 136.

Thus, when the first device body 110 and the second device body 120 are opened or closed the intermediate linear portion 230 of the flexible substrate 200 is twisted, and thereby contracts in a left and right direction, which corresponds to a longitudinal direction thereof.

Such state of the intermediate linear portion 230 displaces the first linear portion 210 continuously formed from the left end portion thereof to the right, and the second linear portion 220 continuously formed from the right end portion thereof to the left. However, since the first linear portion 210 circumvents the end portion of the first opening 112, and the second linear portion 220 circumvents the end portion of the second opening 122.

Accordingly, even though the intermediate linear portion 230 of the flexible substrate 200 is twisted by the opening or closing action of the first device body 110 and the second device body 120, the first linear portion 210 is prevented from interfering with the end portion of the first opening 112, and also the second linear portion 220 is prevented from interfering with the end portion of the second opening 122, and therefore a trouble such as wire disconnection because of the interference can be prevented.

The mobile phone terminal 100 according to this embodiment easily and surely eliminates the trouble of the flexible substrate 200 without the need to largely modify the design of essential components, such as enlarging the first and the second opening 112, 122 of the first and the second device body 110, 120, or changing the position of the connector 135, 136 of the first and the second rigid substrate 133, 134, as stated earlier.

Also, in the mobile phone terminal 100 according to this embodiment, the first and the second linear portion 210, 220 of the flexible substrate 200 are formed in an arcuate curve so as to circumvent the first and the second opening 112, 122, and the rear edge portion of the intermediate linear portion 230 and the inner edge portion of the arcuate recessed portion 211 of the first linear portion 210 are continuous with each other.

Accordingly, even though the flexible substrate 200 incurs distortion or the like originating from the opening or closing action of the first device body 110 and the second device body 120, concentration of stress can be suppressed. This also leads to prevention of troubles such as disconnection of the flexible substrate 200. Further, signal lines provided in the flexible substrate 200 are also formed in a smooth curve, and hence generation of noise due to reflection in electrical signals being transmitted can be suppressed.

It is to be understood that the present invention is not limited to the foregoing embodiment, but encompasses various modifications within the scope and spirit of the present invention. For example, the opening/closing type electronic device is exemplified by the mobile phone terminal 100 in the embodiment.

The present invention is, however, applicable to various other opening/closing type electronic devices that include a first device body and a second device body openably and closably connected via a hollow hinge portion through which a flexible substrate is inserted, such as a personal digital assistance (PDA) and a laptop computer (not shown).

Also, though the first and the second linear portion 210, 220 of the flexible substrate 200 are both formed in the curved shape so as to circumvent the end portion of the first and the second opening 112, 122 in the foregoing embodiment, only either of those portions may be formed in the curved shape (not shown).

Also, the embodiment exemplifies the case where the flexible substrate 200 is of a simple single-sheet structure. However, the flexible substrate may be constituted of a plurality of stacked layers (not shown).

Such multilayer flexible substrate may be formed by stacking a plurality of flexible substrates, or folding a single flexible substrate thereby superposing the folded portions on one another (not shown).

Further, the embodiment exemplifies the case where the first and the second linear portion 210, 220 of the flexible substrate 200 are formed in an arcuate curve so as to circumvent the first and the second opening 112, 122 respectively.

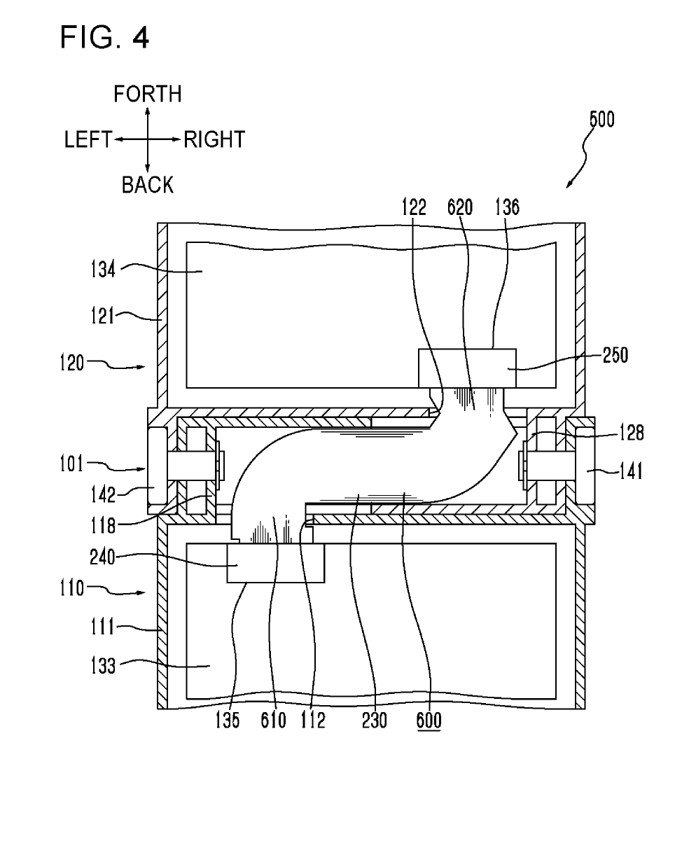

However, as a flexible substrate 600 of a mobile phone terminal 500 shown in FIG. 4, a first and a second linear portion 610, 620 may be formed so as to circumvent the first and the second opening 112, 122 in a rectangular or a triangular shape.

Further, the embodiment exemplifies the case where the flexible substrate 200 is of such a shape that connects the first rigid substrate 133 in the first body housing 111 and the second rigid substrate 134 in the second body housing 121 via a shortest distance.

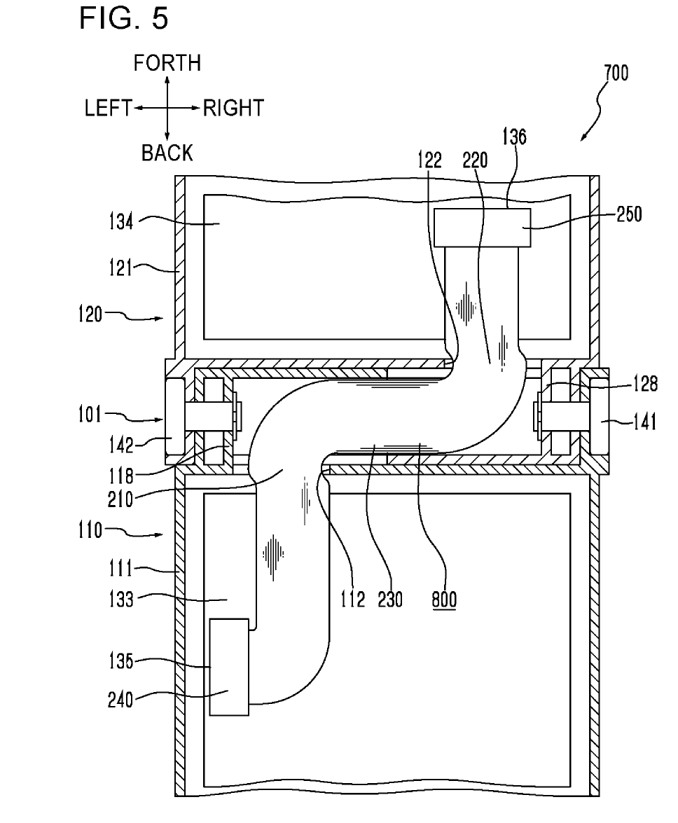

However, as a mobile phone terminal 700 shown in FIG. 5, the flexible substrate 800 may be formed in a sufficient length, so as to be connected at a position spaced from the respective end portion of the first rigid substrate 133 in the first body housing 111 and the second rigid substrate 134 in the second body housing 121.

The mobile phone terminal 700 can effectively prevent, because of the sufficient length given to the flexible substrate 800, the disconnection thereof provoked by the opening and closing action of the first body housing 111 and the second body housing 121.

Still further, the embodiment exemplifies the case where the connectors 240, 250 provided at the end portions of the flexible substrate 200 are respectively connected to the first rigid substrate 133 and the second rigid substrate 134, parallel to the end portions thereof.

However, as the mobile phone terminal 700 shown in FIG. 5, either or both of the connectors 240, 250 of the flexible substrate 800 may be connected to the first rigid substrate 133 and the second rigid substrate 134, orthogonally to the end portions thereof.

1. A flexible substrate, of a flat shape and including a first linear portion, an intermediate linear portion, and a second linear portion continuously formed in a crank shape,
wherein a left end portion of said intermediate linear portion having a shape prolonged in a left and right direction is continuous with a front end portion of said first linear portion having a shape prolonged in a back and forth direction;
a rear end portion of said second linear portion having a shape prolonged in a back and forth direction is continuous with a right end portion of said intermediate linear portion; and
said first linear portion includes a recessed portion at least on a right edge portion thereof.

2. The flexible substrate according to claim 1,
wherein said first linear portion is of such a recessed shape that an intermediate portion thereof protrudes in a left direction, at least from said front end portion and a rear end portion thereof.

3. The flexible substrate according to claim 2,
wherein said first linear portion has said intermediate portion recessed in a left direction in an arcuate curve.

4. The flexible substrate according to claim 3,
wherein a rear edge portion of said intermediate linear portion is continuous with an inner edge portion of said recessed portion of said first linear portion, and said recessed portion is formed in an arcuate shape.

5. The flexible substrate according to claim 1,
wherein said second linear portion includes a recessed portion at least on a left edge portion thereof.

6. The flexible substrate according to claim 1,
wherein said intermediate linear portion is included in a hollow hinge portion openably and closably connecting a first device body and a second device body of an opening/closing type electronic device, and at least said rear end portion of said first linear portion is included in said first device body; and at least a front end portion of said second linear portion is included in said second device body.

7. The flexible substrate according to claim 6,
wherein said first device body includes a first cylindrical hinge portion including a first opening and constituting a part of said hollow hinge portion; and
said recessed portion of said first linear portion is located so as to oppose a right end surfaced of said first opening, with a gap therebetween.

8. An opening/closing type electronic device including a first device body and a second device body openably and closably connected via a hollow hinge portion through which a flexible substrate is inserted,
wherein said first device body includes a first cylindrical hinge portion including a first opening and constituting a part of said hollow hinge portion;
said first linear portion of said flexible substrate according to claim 7 is inserted through said first opening; and
said recessed portion of said first linear portion is located so as to oppose a right end inner surface of said first opening, with a gap therebetween.
